(19) United States
(12) Patent Application Publication
(10) Pub. No.: US 2005/0229050 A1
(43) Pub. Date: Oct. 13, 2005

(54) Semiconductor device

(75) Inventor: Kazushige Kanda, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/998,949

(22) Filed: Nov. 30, 2004

(30) Foreign Application Priority Data
Apr. 7, 2004 (JP) 2004-112910

(51) Int. Cl. G11C 29/00

(52) U.S. Cl. 714/718

(57) ABSTRACT

A semiconductor device comprises a first supply voltage pad arranged to apply a first supply voltage; and a second supply voltage pad arranged to apply a second supply voltage for execution of tests. A current detector is operative to detect a current caused from application of the second supply voltage to the second supply voltage pad. A controller is operative to cut off or suppress supply of the second supply voltage to the second supply voltage pad based on a detected output from the current detector.

### CROSS-REFERENCE TO PRIOR APPLICATION

This application is based upon and claims the benefit of priority from the prior Japanese Patent Application No. 2004-112910, filed on Apr. 7, 2004, the entire content of which is incorporated herein by reference.

### BACKGROUND OF THE INVENTION

1. Field of the Invention

The present invention relates to a semiconductor device formed in a semiconductor wafer as one of a plurality of semiconductor chips (hereinafter simply referred to as “chips”).

2. Description of the Related Art

In the process steps of manufacturing semiconductor devices, semiconductor chips are generally subjected to die sort tests (hereinafter referred to as DS tests), for example, testing of various characteristics and functions in bare chip state before packaging. DS tests may often be performed not only after dicing but also in the state of semiconductor wafer before dicing. As shown in a flowchart of FIG. 12, DS tests are performed in the state of semiconductor wafer (S1). If it is determined that failures/defects are found as a result of DS tests though they can be relieved, redundancy replacement is performed with, for example, fuse blow. In addition, based on the measured electric characteristic, trimming of various internally generated voltages is performed (S2). Chips that are determined excellent and chips that are failure-relieved are assembled after dicing (S3). After a final evaluation of the assembled product is completed (S4), the product turns in a final product that can be shipped out.

As shown in a flowchart of FIG. 13, DS tests are roughly classified into three: a DC test (S11), a function test (S12), and a margin test (S13). The DC test (S11) is a measurement to the most basic parts in a chip for testing whether each pin is in contact with a tester probe (contact check); whether various currents (such as a standby current in a flash memory) have suitable values; whether leakage currents from a supply voltage pin, an input/output signal pin and a control signal pin (pin leakage currents) are present; and whether internally generated voltages have desired values.

If no problem is found in the DC test, the function test (S12) is executed for testing whether the chip can serve a desired function. For example, if the chip comprises a flash memory, the test is performed on whether the chip can perform basic operations such as device ID reading, data reading, writing, erasing, and all “0” writing. The margin test (S13) is for testing how accurately the memory cells are finished. For example, in the case of the flash memory, the test is performed to check whether an interference is present between cells by checker pattern (C) or checker bar pattern (/C) writing, reading and erasing.

During the DS tests in the semiconductor wafer state, a plurality of chips formed in the wafer are subjected to batch probing for the purpose of test efficiency (see JP-A 2002-33360, for example). Namely, as shown in FIG. 14, a plurality of chips 2 formed in the wafer 1 are probed in batch and a supply voltage is applied from the tester simultaneously thereto.

When the DS tests are performed, it is desirable for improvement of the test efficiency as described above to connect as many chips as possible in parallel simultaneously to the tester and finish testing as many chips as possible at a time.

In the DC test (S11 of FIG. 13) of the DS tests, however, as shown in FIG. 15, one or more of the plurality of chips connected for batch probing may be failed chips (indicated with the reference numeral 2F in FIG. 15). A leakage current may flow in the failed chip 2F possibly. The leakage current causes a voltage drop across a parasitic resistance associated with a probe line 4 connected to the failed chip 2F. An increasing number of the failed chips 2F cause an extremely large current to flow in the probe line 4 totally. As a result of the voltage drop caused by the current, for example, a sufficient voltage can not be applied to a chip 2 connected to a distal end of the probe line 4 and accordingly a precise DC test may not be performed possibly. In order to avoid this problem, the tester itself may be configured to supply such the large current. Though, such the configuration results in an expensive tester and invites an increased test cost. Thus, the number of chips possibly connected for batch probing is limited and an improvement of the test efficiency is prevented.

### SUMMARY OF THE INVENTION

The present invention provides a semiconductor device, which comprises a first supply voltage pad arranged to apply a first supply voltage; a second supply voltage pad arranged to apply a second supply voltage for execution of tests; a current detector operative to detect a current caused from application of the second supply voltage to the second supply voltage pad; and a controller operative to cut off or suppress supply of the second supply voltage to the second supply voltage pad based on a detected output from the current detector.

### BRIEF DESCRIPTION OF THE DRAWINGS

FIG. 1 shows a configuration of a semiconductor chip 2 according to a first embodiment of the present invention;

FIG. 2 shows a configuration example of a cell array 11 in a NAND-type flash memory as the semiconductor chip 2 shown in FIG. 1;

FIG. 3 shows a configuration example of a switching circuit 6 shown in FIG. 1;

FIG. 4 shows specific configuration examples of switches 22 and 23 shown in FIG. 3;

FIG. 5 shows a specific configuration example of a voltage detector 25 shown in FIG. 3;

FIG. 6 shows a specific configuration example of a switch controller 26 shown in FIG. 3;

FIG. 7 is a timing chart showing operations of the semiconductor chip 2 according to the first embodiment;

FIG. 8 shows a configuration of a semiconductor chip 2 according to a second embodiment of the present invention;

FIG. 9 shows a configuration of a semiconductor chip 2 according to a third embodiment of the present invention;

FIG. 10 shows a configuration of a semiconductor chip 2 according to a fourth embodiment of the present invention;

FIG. 11 shows a specific configuration example of a step-down circuit 28 shown in FIG. 10;

FIG. 12 is a flowchart showing semiconductor test steps for execution of die sort tests in a semiconductor wafer state before dicing;

FIG. 13 is a flowchart showing the steps of the die sort tests;

FIG. 14 shows a structure of a conventional semiconductor wafer 1; and

FIG. 15 shows a problem on the conventional semiconductor wafer 1.

### DETAILED DESCRIPTION OF THE PREFERRED EMBODIMENTS

A first embodiment of the present invention will now be described with reference to the drawings, in which the same elements as those in the prior art are given the same reference numerals and omitted to detail below.

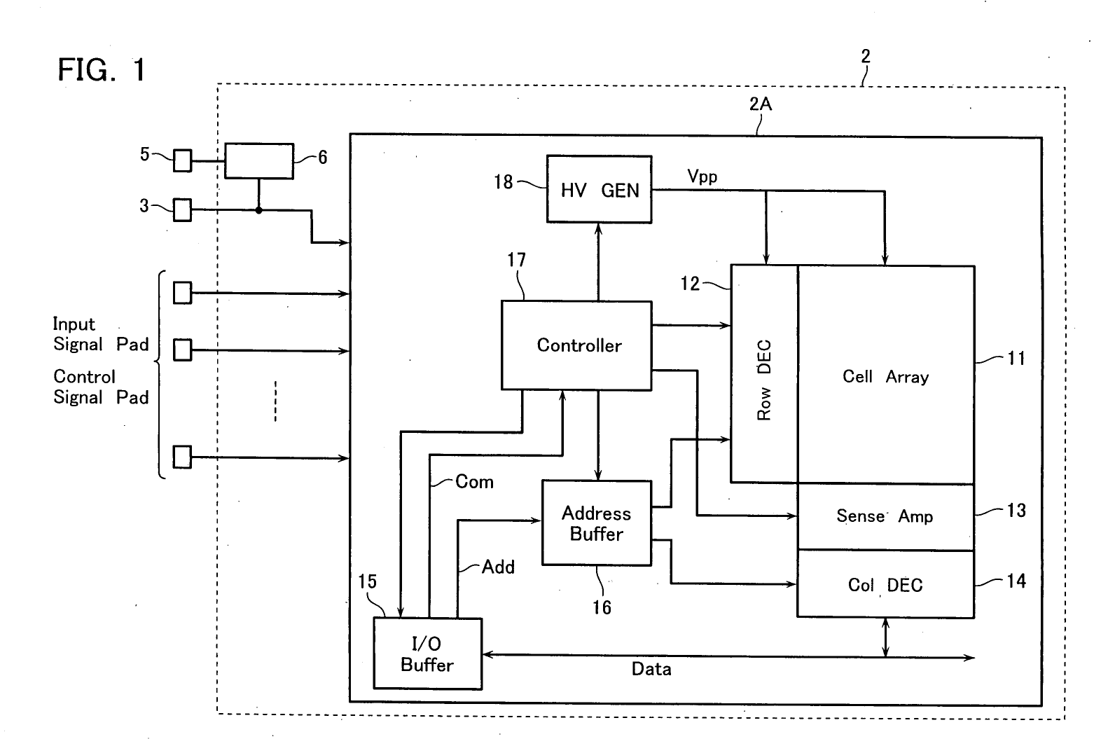

A semiconductor chip 2 according to the embodiment of the present invention comprises, as shown in FIG. 1, a normal supply voltage pad 3 and additionally a DS test supply voltage pad 5, which is to be connected to a tester during DS tests. The DS test supply voltage pad 5 supplies a supply voltage via a switching circuit 6 to a circuit group 2A. In this embodiment the semiconductor chip 2 will be described as a NAND-type flash memory.

The switching circuit 6 has a function to electrically connect the DS test supply voltage pad 5 to the circuit group 2A at the beginning of DS tests, and separate the DS test supply voltage pad 5 from the circuit group 2A in the certain cases described later.

The circuit section 2A includes various circuits 11-18 for configuring the NAND-type flash memory. A cell array 11 includes a plurality of floating gate memory cells MC arrayed in matrix. A row decoder (containing word line drivers) 12 drives word lines and selection gate lines in the cell array 11. A sense amp circuit 13 includes sense amps and data holders for one page to configure a page buffer that writes and reads data to and from the cell array 11 on a page basis.

One page of read data from the sense amp circuit 13 is selected at a column decoder (column gate) 14, which outputs it via an I/O buffer 15 to an external I/O terminal. Write data supplied from the I/O terminal is selected at the column decoder 14, which loads it to the sense amp circuit 13. One page of write data is loaded in the sense amp circuit 13 and held until a write cycle terminates. An address signal is input via the I/O buffer 15 and transferred to the row decoder 12 and the column decoder 14 via an address buffer 16.

A controller 17 provides various internal timing signals for timing control of data reading, writing and erasing based on external control signals such as a write enable signal /WE, a read enable signal /RE, an address latch enable signal ALE and a command latch enable signal CLE. Further, the controller 17 performs sequence control of data writing and erasing and operation control of data reading based on these internal timing signals. A high-voltage generator 18 generates various high voltages Vpp for use in data writing and erasing under control of the controller 17. On testing of the NAND-type flash memory, the tester feeds supply voltages and various signals for testing via the supply voltage pads 3, 5 and various input/output signal pads and control signal pads.

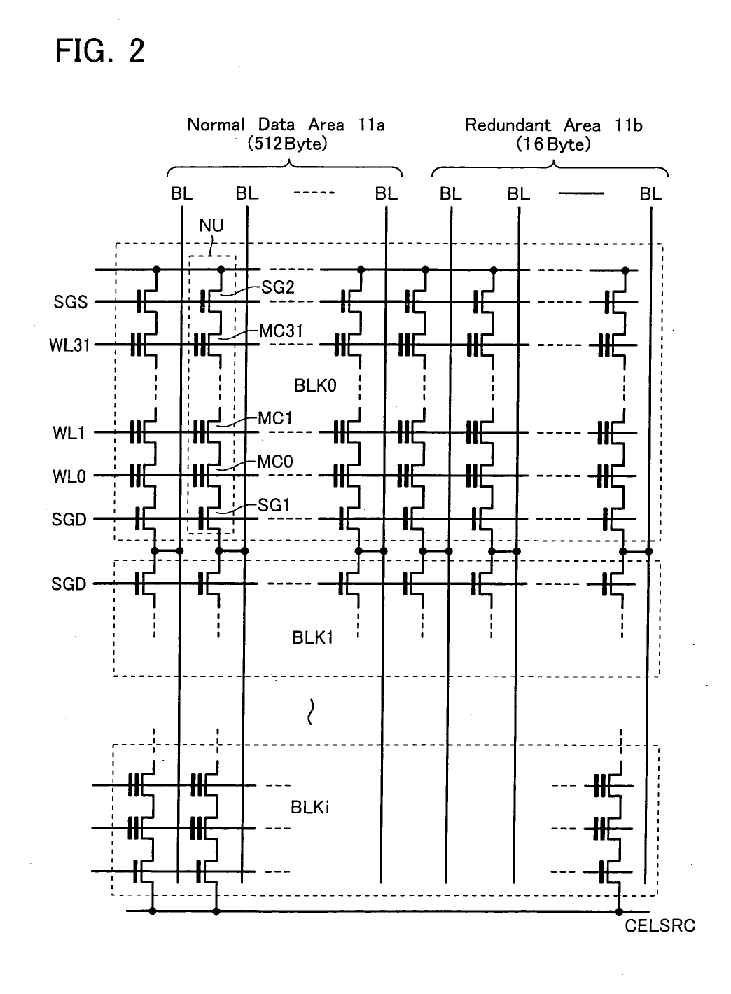

FIG. 2 shows a detailed configuration of the cell array 11. The cell array 11 includes an array of NAND cell units NU each having a plurality (32 in the shown example) of floating gate memory cells MC0-MC31. A NAND cell unit NU consists of a cell string of serially connected memory cells MC0-MC31; a selection gate transistor SG1 located between an end of the cell string and a bit line BL; and a selection gate transistor SG2 located between the other end of the cell string and a source line CELSRC.

The memory cells MC0-MC31 have gates connected to different word lines WL0-WL31, respectively. The selection gate transistors SG1 and SG2 have gates connected to selection gate lines SGD and SGS extending along the word lines WL0-WL31. A set of memory cells arranged along one word line configures one page. A set of NAND cell units NU arranged in the word line direction configures one block. The cell array 11 of FIG. 2 has a plurality of blocks BLK0-BLK1 arranged in the bit line direction.

Each page in the cell array 11 is divided into a normal data region 11a for normal data storage and a redundant region 11b. For example, the normal data region 11a has 512 bytes. The redundant region 11b has 16 bytes and includes a region to store ECC data, logical addresses, and flags indicative of the quality of blocks for error bit correction of data in the normal data region 11a.

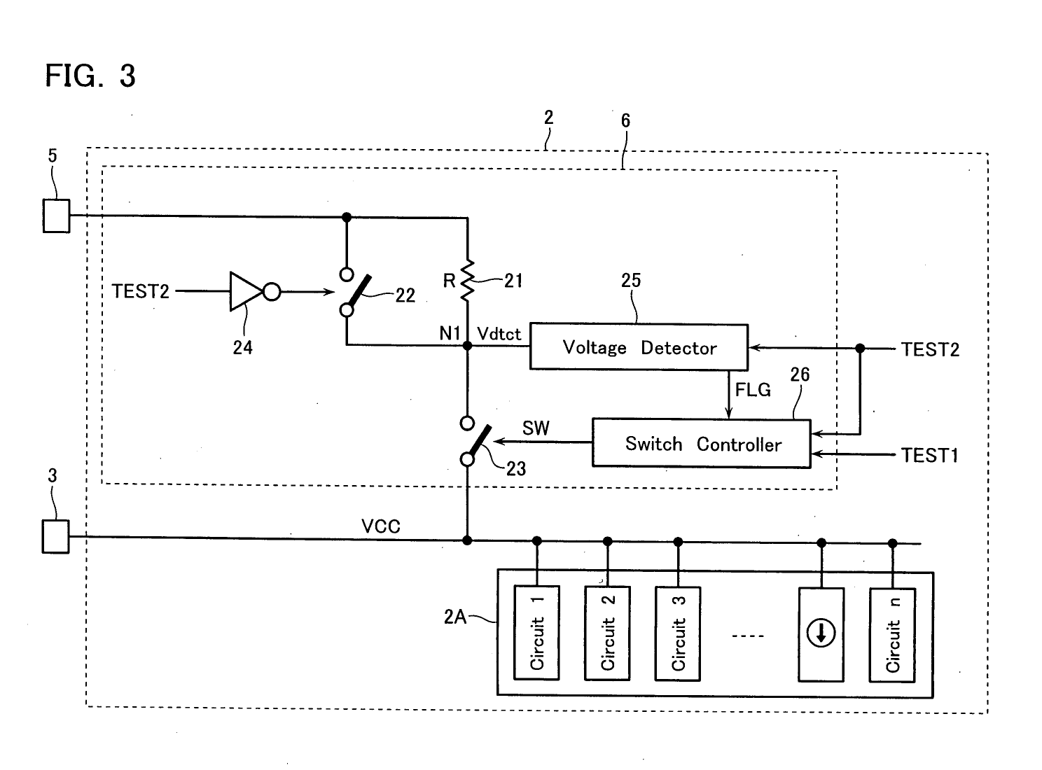

A specific configuration of the switching circuit 6 is described with reference to FIG. 3. As shown in FIG. 3, the switching circuit 6 receives two switching signals TEST1 and TEST2 input from the controller 17 of FIG. 2. The switching signal TEST1 is a signal indicative of beginning DS tests. The switching signal TEST2 is a signal indicative of beginning the DC test of DS tests. These are signals generated in the controller 17 based on inputs of external control signals.

The switching circuit 6 includes a resistor 21 and switches 22, 23 as shown in FIG. 3. The resistor 21 and the switch 23 are connected serially between the DS test supply voltage pad 5 and the circuit group 2A. The switch 23 will be turned on at the beginning of DS tests and turned off on detection of more than a certain value of current flowing in the resistor 21 as described later.

The switch 22 is connected in parallel with the resistor 21 and will be turned on when other tests of DS tests than the DC test (function and margin tests) are executed. Thus, the switch 22 has a role to short-circuit across the resistor 21 on execution of the function test and the margin test. The switch 22 is turned on/off by an inverted signal of the switching signal TEST2 from an inverter 24.

The switching circuit 6 further includes a voltage detector 25 and a switching controller 26. The voltage detector 25 detects a voltage Vdtct at a node N1 downstream from the resistor 21. It changes a detection signal FLG if it determines that the current flowing in the resistor 21 has a value larger than a certain value when Vdtct lowers below a reference value VREF. The voltage detector 25 is configured to receive the switching signal TEST2 indicative of beginning/ending of the DC test of DS tests, which is input from the tester not shown. When the switching signal TEST2 turns to “H”, the voltage detector 25 transits the state from standby to active and begins operation.

The switching controller 26 is operative to control the switch 23 and provide a control signal SW to turn off the switch 23 when the detection signal FLG from the voltage detector changes.

The switching controller 26 is configured to receive the switching signal TEST1 indicative of beginning DS tests and the switching signal TEST2 input from the controller 17. When the switching signal TEST1 turns from “L” to “H”, the switching controller 26 turns the switch 23 from off to on to enable DS tests to start with the DS test supply voltage pad 5.

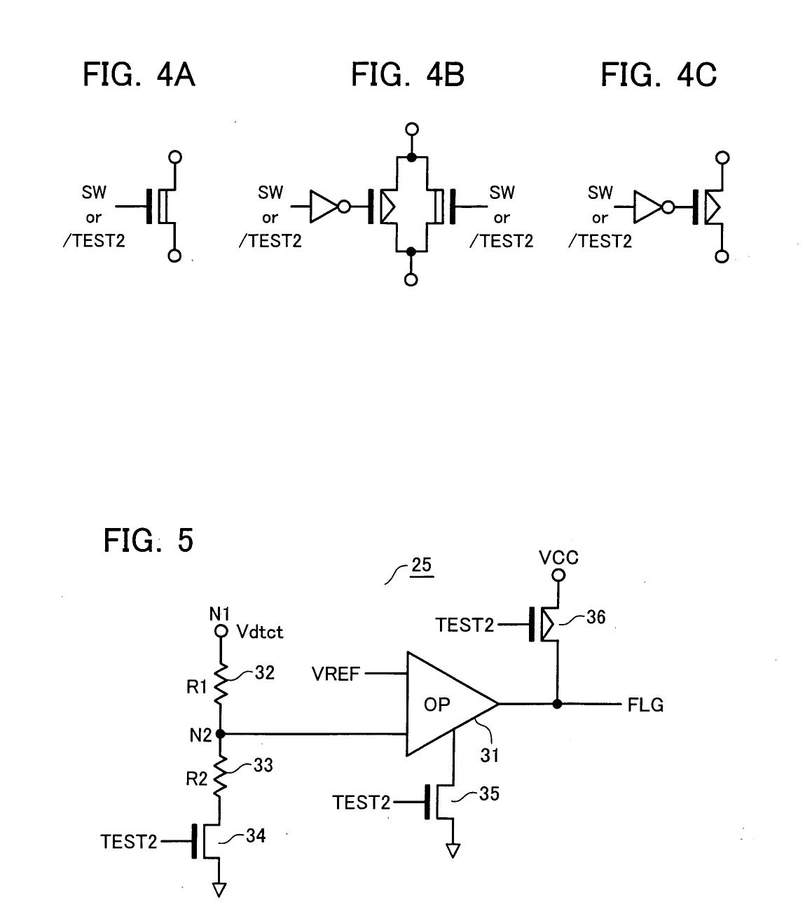

As shown in FIG. 4, the switches 22 and 23 may be composed of a single D-type NMOS transistor as shown in FIG. 4A; a PMOS transistor and an D-type NMOS transistor connected in parallel as shown in FIG. 4B; and a single PMOS transistor as shown in FIG. 4C. In FIG. 4C, the same operation as the switch of FIG. 4A can be performed if the input signal is inverted through an inverter.

FIG. 5 shows a specific configuration of the voltage detector 25. The voltage detector 25 includes an opamp 31 serving as a comparator; resistors 32 and 33 configuring a resistance divider; and switches 34-36 for switching operation/non-operation of the whole circuit. The opamp 31 serves as a comparator that compares a detected voltage with the reference voltage VREF generated in a well-known, band-gap reference voltage generator (not shown) or the like.

The resistors 32 and 33 are serially connected at a node N2. The other end of the resistor 32 is connected with the node N1. The other end of the resistor 33 is grounded via the switch 34. When the switch 34 is turned on, a voltage, R2×Vdtct/(R1+R2), appears at the node N2. The opamp 31 receives the voltage at one of the input terminals and compares it with the reference voltage VREF.

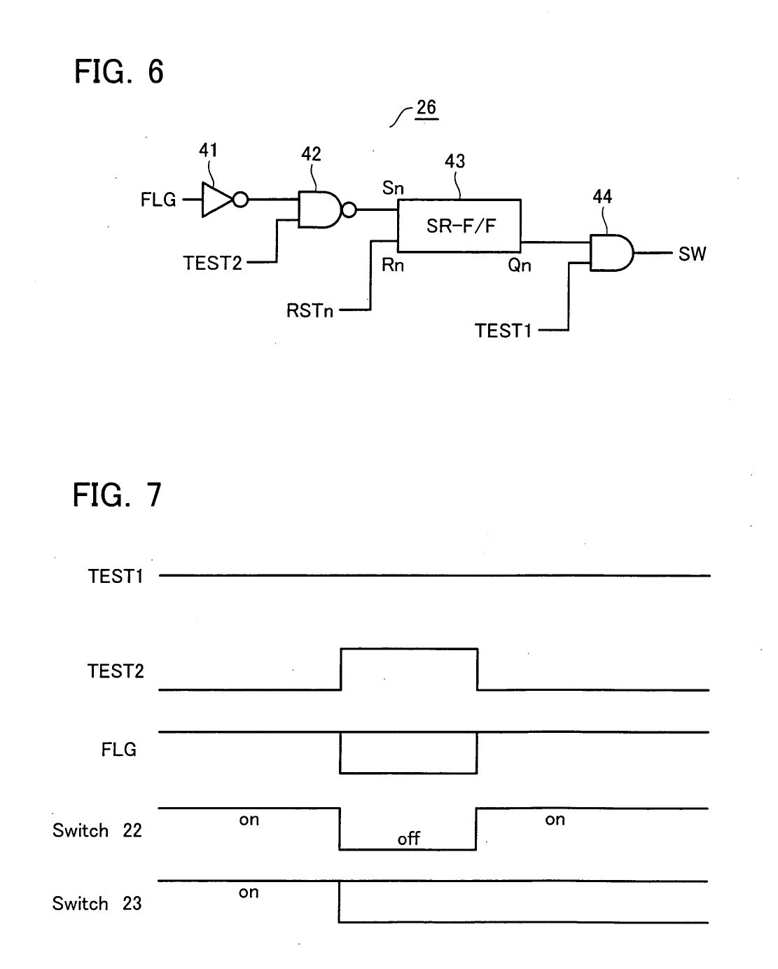

As shown in FIG. 6, the switching controller 26 includes an inverter 41, a NAND circuit 42, a SR flip-flop circuit (SR-FF circuit) 43 and an AND circuit 44.

The NAND circuit 42 provides a NAND output of the switching signal TEST2 and the inverted signal of the detection signal from the inverter 41. The SR-FF circuit 43 is configured to receive the output signal from the NAND circuit 42 as an input to the Sn terminal. It also receives a reset signal RSTn generated at the time of power-on or in synchronization with the rise of the TEST2 signal as an input to the Rn terminal.

The SR-FF circuit 43 is a latch circuit that has a function to reset the output from the Qn terminal into a “H” signal when the power-on reset signal RSTn enters the Rn terminal. It sets the output from the Qn terminal into an “L” signal when an “L” signal enters the Sn terminal. The AND circuit 44 provides an AND output of the switching signal TEST1 and the output from the Qn terminal of the SR-FF circuit 43.

Operation of the switching circuit 26 on DS tests is described with reference to a flowchart of FIG. 7.

After the beginning of DS tests, the switching signal TEST1 is turned to “H”, which causes the switching controller 26 to execute operation of turning on the switch 23. Before beginning the DC test of DS tests, the switching signal TEST2 is kept “L”, which holds the switch 22 turned on to short-circuit across the resistor 21.

When the switching signal TEST2 its turned to “H” to begin DS tests, the switch 22 is turned off and thus the supply voltage from the DS test supply voltage pad 5 suffers a voltage drop across the resistor 21. The magnitude of the voltage drop is detected as the voltage Vdtct at the node N1 by the voltage detector 25 that is made active when the switching signal TEST2 is turned to “H”.

When a leakage current occurs because of a failure or defect present in any of the circuits 1-n of the circuit group 2A, it increases a total current flowing in the resistor 21. As a result, if the voltage detector 25 determines that the voltage at the node N1 is below the detection voltage Vdtct (=VREF·(R1+R2)/R2), it provides the detection signal FLG output as an “L” signal. Thus, a signal “H” is latched in the SR-FF circuit 43 of the switching controller 26. Then, the control signal SW is turned to “L”, which turns the switch 23 off to halt the application of the supply voltage to the semiconductor chip 2, in which the leakage current is detected. Even after the DC test is finished and the switching signal TEST2 is turned to “L”, the latched data Qn in the SR-FF circuit 43 is kept “H” to hold the switch 23 turned off. Accordingly, the application of the supply voltage to the leakage current-detected semiconductor chip 2 is still halted during the subsequent function and margin tests. Therefore, failed chips are prevented from affecting on the test results on excellent chips.

As shown in FIG. 7, the switching signal TEST1 is always kept “H” during execution of DS tests. Accordingly, the supply voltage applied from the tester to the DS test supply voltage pad 5 may be employed as the switching signal TEST1 as it is.

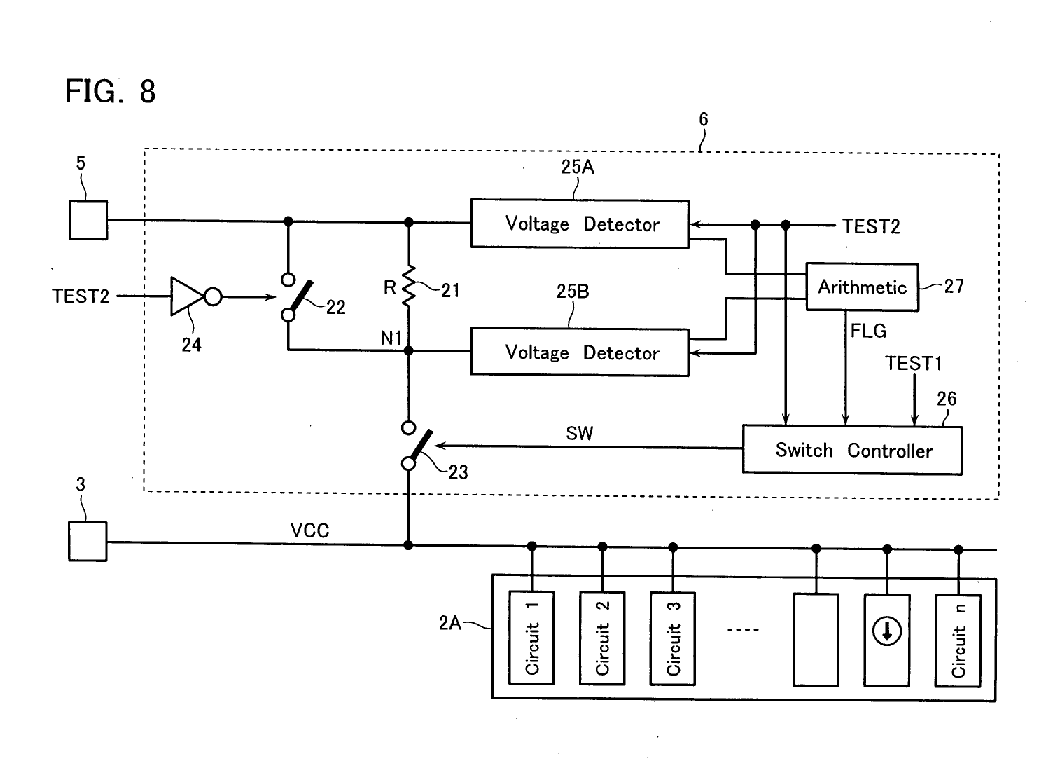

A second embodiment of the present invention will be described with reference to FIG. 8. In this embodiment, the voltage detector 25 is provided as two voltage detectors: one 25A for detecting the voltage at the DS test supply voltage pad 5; and another 25B for detecting the voltage at the node N1. An arithmetic circuit 27 operates a difference between the two detected results to detect the magnitude of the current flowing in the resistor 21. In accordance with this configuration, even if the supply voltage applied from the tester via the DS test supply voltage pad 5 fluctuates, the current can be detected precisely regardless of the fluctuation.

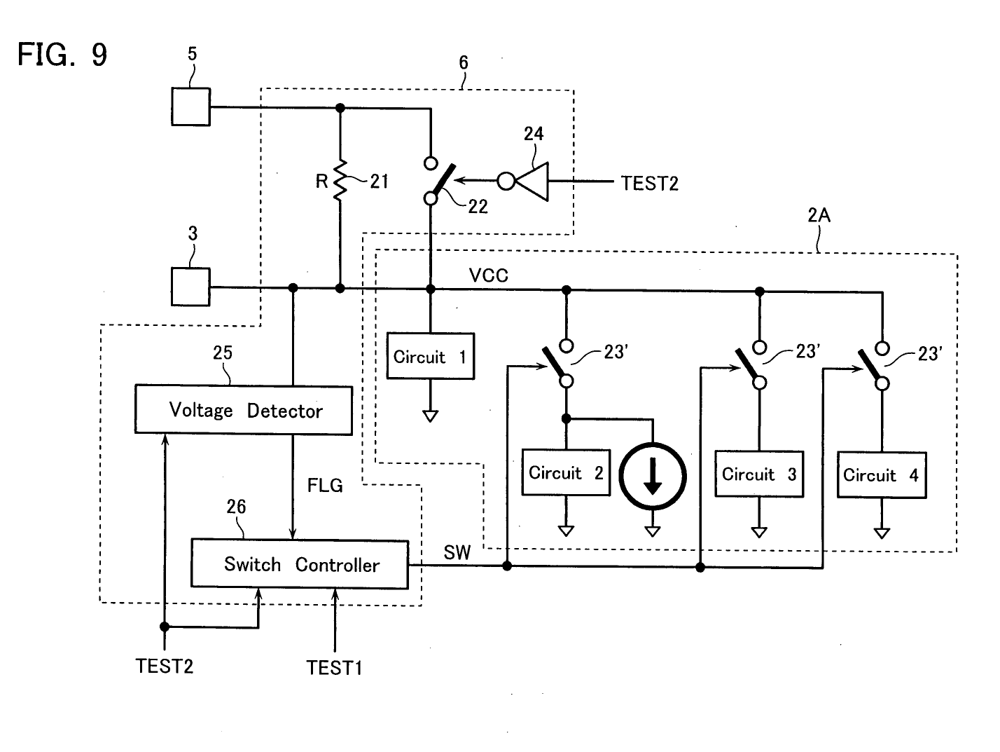

A third embodiment of the present invention will be described with reference to FIG. 9. In this embodiment, switches 23′ are provided on respective branch lines to the circuits 1-4 in the circuit group 2A as shown in FIG. 9. This point is different from the first embodiment. The switch 23′ may be provided only to the circuits 2-4 that consume a small current during normal operation and not to the circuit 1 that consumes a large current even during normal operation. If the switch 23′ is provided to the circuit 1 that consumes a large current even during normal operation, the required consumption current may not be supplied possibly. In this embodiment, a leakage current can not be prevented when a failure or defect is present in the circuit 1. Nevertheless, if a proportion occupied by the circuit 1 in the circuit group 2A is small, it is possible to achieve almost the same effect as that in the above embodiment.

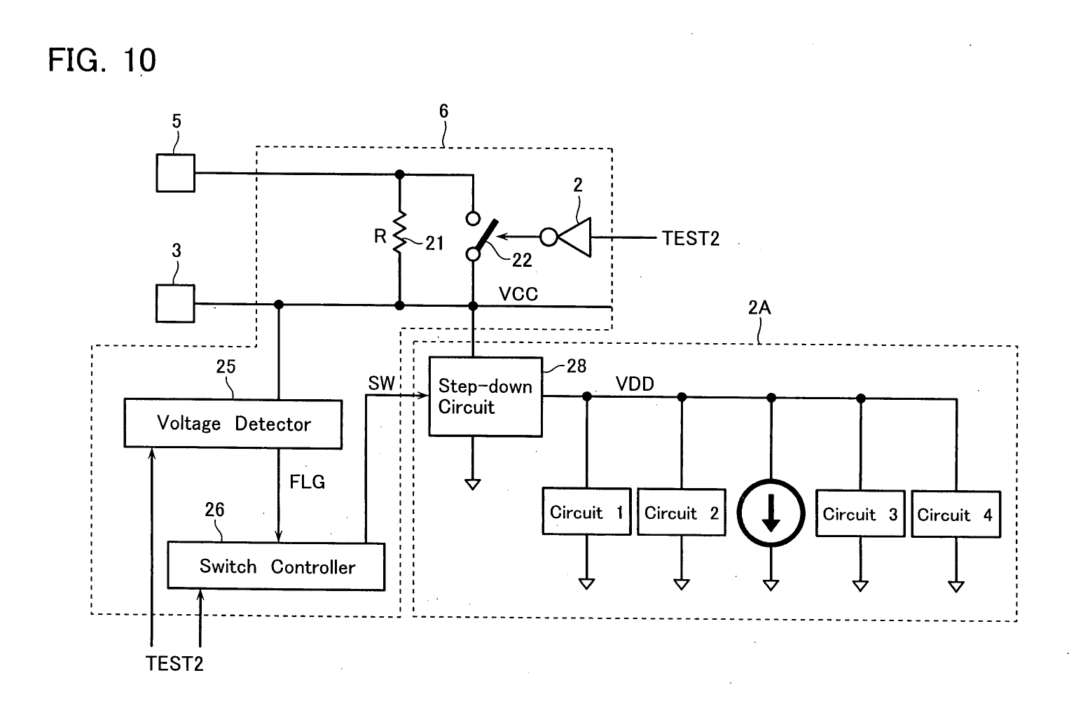

A fourth embodiment of the present invention will be described with reference to FIG. 10. In this embodiment, a step-down circuit 28 is provided instead of the switch 23 as shown in FIG. 10 to drop the supply voltage Vcc down to a certain voltage VDD. When a leakage current increases over a certain value, the voltage VDD applied to the circuit group 2A is further lowered.

The step-down circuit 28 may include an opamp 50 serving as a comparator; switches 51 and 52; a PMOS transistor 53; an NMOS transistor 54; an inverter 55; D-type NMOS transistors 56 and 57; resistors 58 and 59; and a switch 60. The opamp 50 is configured to receive at input terminals a voltage on a connection node N4 between the resistors 58 and 59 and a reference voltage VREF′ for comparison of both. The switches 51 and 52 change operation/non-operation of the opamp 50. The output terminal of the opamp 50 is connected to the gate of the PMOS transistor 53. The PMOS transistor 53 is connected serially to the NMOS transistor 54.

The NMOS transistor 54 is controlled on/off using an inverted signal of the control signal SW, which is output from the switch controller 26 and inverted by the inverter 55. The drain of the PMOS transistor 53 is connected to the gates of the D-type NMOS transistors 56 and 57. The gate terminals of the D-type NMOS transistors 56 and 57 are controlled to present a certain voltage on the source terminal of the transistor 57 and the source terminal of the transistor 56.

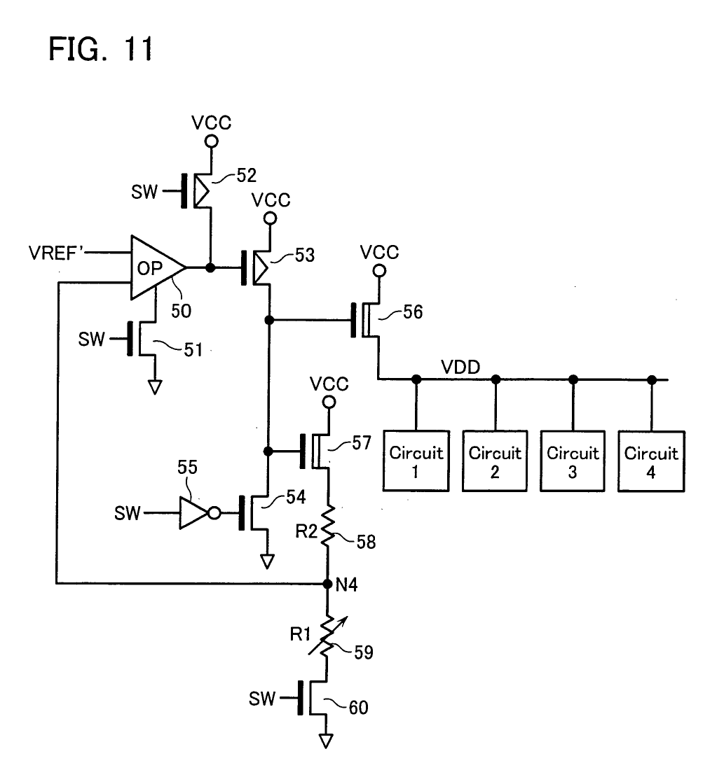

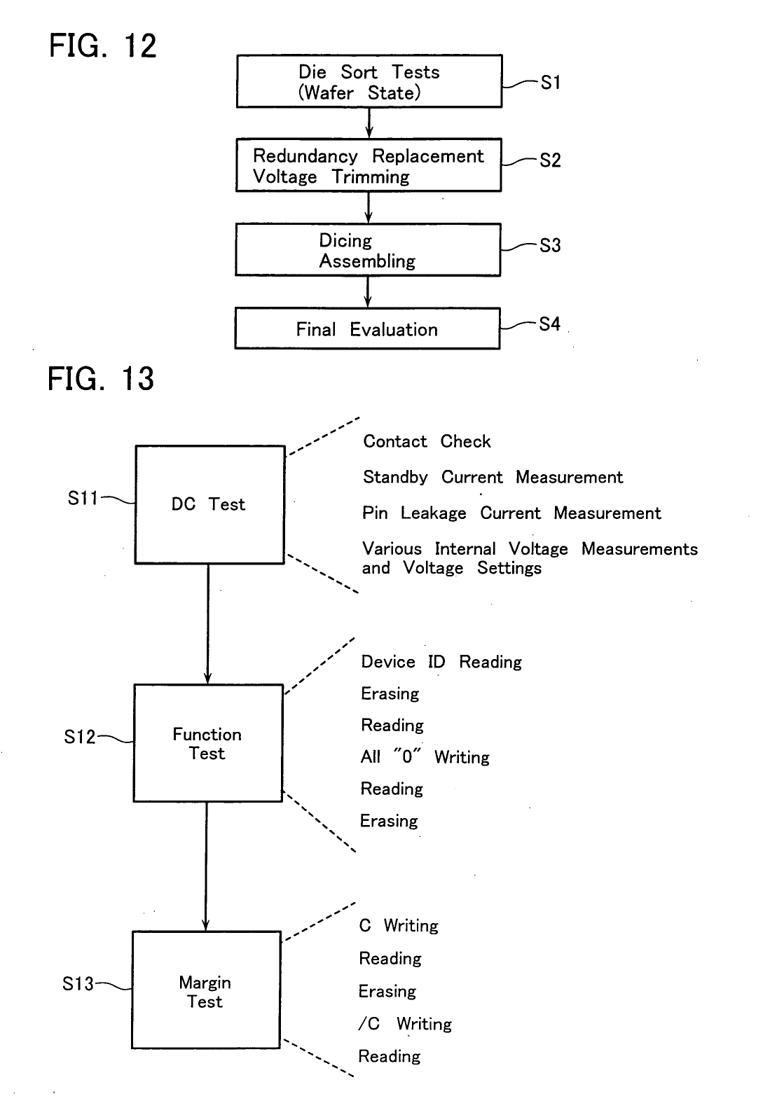

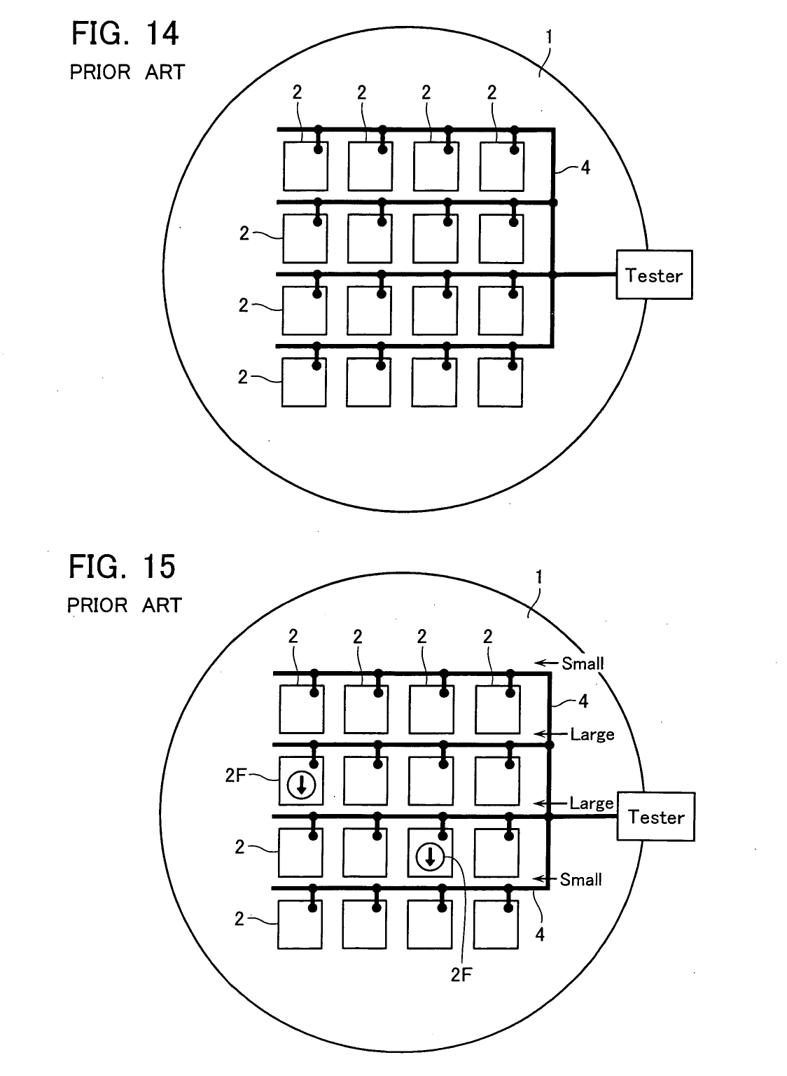

Operations of the circuit in FIG. 11 are classified for description into the case of the control signal SW being on (the leakage current from the test line is below a certain value) and the case of the control signal SW being off.

The former case is described first. When the voltage at the connection node N4 between the resistors 58 and 59 is fed back to one of the input terminals of the opamp 50, the voltage at the connection node N4 is kept equal to the reference voltage VREF. As a result, the voltages on the gates of the D-type NMOS transistors 56 and 57 are kept constant, and thus the voltage VDD is also kept constant.

In the latter case, on the other hand, the opamp 50 is turned to the state of non-operation and the above-described feed back control is not performed. The NMOS transistor 54 is on the other hand turned on to pull the gate voltage at the D-type NMOS transistor 56 down to the ground voltage. At the same time, the voltage VDD on the test line 4 lowers more than the case when the opamp 30 operates. This is effective to suppress the supply of current to a failed chip having a large leakage current and test an excellent chip more precisely.

The invention has been described on the embodiments above though the present invention is not limited to these embodiments. Rather, various modifications, additions and replacements can be achieved without departing from the scope and spirit of the invention.

1. A semiconductor device, comprising:
a first supply voltage pad arranged to apply a first supply voltage;
a second supply voltage pad arranged to apply a second supply voltage for execution of tests;
a current detector operative to detect a current caused from application of said second supply voltage to said second supply voltage pad; and
a controller operative to cut off or suppress supply of said second supply voltage to said second supply voltage pad based on a detected output from said current detector.

2. The semiconductor device according to claim 1, wherein said current detector functions on execution of a DC test of die sort tests.

3. The semiconductor device according to claim 1, further comprising:
an electric resistor connected between said second supply voltage pad and a circuit section; and
a short circuit unit operative to short-circuit across said electric resistor on execution of tests of die sort tests other than said DC test,
wherein said current detector detects the magnitude of a voltage drop across said electric resistor to detect said current.

4. The semiconductor device according to claim 1, further comprising a switch connected between said second supply voltage pad and a test-targeted circuit section,
wherein said controller controls said switch on/off based on a detected output from said current detector.

5. The semiconductor device according to claim 1, further comprising a step-down circuit connected between said second supply voltage pad and a test-targeted circuit section and configured to lower a voltage applied to said circuit section,
wherein said controller controls said step-down circuit based on a detected output from said current detector.

6. The semiconductor device according to claim 5, said step-down circuit including a D-type MOS transistor having a source receiving a supply voltage applied thereto and a drain connected to said circuit section,
wherein said D-type MOS transistor is given a gate voltage, which is retained normally at a first voltage through feed back control, and which is changed to a second voltage by said controller when said current detector detects a certain current.

7. The semiconductor device according to claim 1, said controller including a latch circuit operative to store a detected result from said current detector.

8. The semiconductor device according to claim 7, wherein said latch circuit resets a stored content based on a power-on reset signal output simultaneously with beginning of said DC test of die sort tests.

9. The semiconductor device according to claim 3, said current detector including a first voltage detector operative to detect a voltage applied to said second supply voltage pad; and a second voltage detector operative to detect a voltage at a point downstream from said electric resistor, wherein said current detector is configured to detect said current based on a difference between detected outputs from said first and second voltage detectors.

10. The semiconductor device according to claim 1, wherein said switch is located on a branch line extending to each of a plurality of circuits in said circuit section.
